(19) United States
(12) Patent Application Publication
(10) Pub. No.: US 2009/0159117 A1
(43) Pub. Date: Jun. 25, 2009

(54) HOT MELT SEALANT CONTAINING DESICCANT FOR USE IN PHOTOVOLTAIC MODULES

(75) Inventors: Louis A. Ferri, Solon, OH (US); David L. Golden, Cuyahoga Falls, OH (US)

Correspondence Address: RENNER OTTO BOISSELLE & SKLAR, LLP, 1621 EUCLID AVENUE, NINETEENTH FLOOR, CLEVELAND, OH, 44115, US

(73) Assignee: TruSeal Technologies, Inc., Solon, OH (US)

(21) Appl. No.: 12/332,831

(22) Filed: Dec. 11, 2008

Related U.S. Application Data
(60) Provisional application No. 61/015,310, filed on Dec. 20, 2007.

(51) Int. Cl. H01L 31/048; B32B 37/12

(52) U.S. Cl. 136/251; 156/278

(57) ABSTRACT

A thin film photovoltaic panel and a method for making same including providing a photovoltaic layer on a substrate having at least one edge; a sealant is applied in a liquid form by a pump on a planar surface of the substrate; an adhesive layer is applied between the first substrate and the second substrate, wherein the first adhesive layer is disposed between the photovoltaic layer and at least one of the first and second substrate; and the first and second are secured together to form the thin film photovoltaic panel. The sealant layer includes a desiccant material having a concentration of less than about 20 weight %, which increases the diffusion time lag time for the sealant to reach steady state, thereby extending the duration of the thin film photovoltaic panel.

### FIELD OF THE INVENTION

This invention relates to a hot melt sealant containing desiccant for use in photovoltaic modules and a method for manufacturing same and, more particularly, to a liquid applied, pumpable, hot melt sealant having a desiccant material disposed therein.

### BACKGROUND OF THE INVENTION

Thin film photovoltaic (TFPV) materials, also commonly referred to as solar modules or solar panels, are known to be susceptible to degradation of performance when exposed to atmospheric humidity and oxygen. Solar modules are used outdoors, and are therefore exposed to the elements, including wind, water and sunlight. Solar modules are deleteriously affected primarily by moisture that may permeate into the module, reaching the electrical connections or the photovoltaic (PV) materials. For example, if the front and back substrates are moisture impermeable, the primary path for water to enter the module is through edges of the module if they are permeable. Water penetration into solar modules has been a long-standing problem in the industry. As set forth below, various attempts have been made to reduce moisture penetration into the module.

U.S. Pat. No. 4,578,526 to Nakano et al. teaches a means for improving the durability of thin film photovoltaic (TFPV) devices using cadmium-telluride (Cd—Te)/cadmium-CdS photovoltaic materials by using a low permeability (e.g., low diffusivity and low solubility) laminating layer made from a flouropolymer. Nakano attempts to improve the durability of the TFPV by offsetting the photovoltaic (PV) materials from the edge of the glass substrate to provide a border area for isolating the outermost PV materials from the atmosphere by the width of that border. Thus, Nakano discloses providing a border to increase the length of the diffusion path into the unit and minimizing the thicknesses of the PV layer and laminating layer, which effectively increases the length of the diffusion path into the unit and reduces the cross-section area between the glass substrate and the PV material in the border area and reduces the permeability of the border area.

U.S. Pat. No. 4,633,032 to Oido et al. mentions the following problem areas needing to be addressed in order to produce efficient and commercially viable TFPV modules: 1) protecting the PV materials and electrical conductors from humidity and corrosive gases, such as oxygen; 2) choosing materials and dimensions of an interposed layer between the PV layer and the front and rear substrates to prevent strain effects due to different thermal expansion coefficients in the various layers; 3) providing sufficient mechanical strength of the module to resist catastrophic damage from environmental forces while also preventing flexing of the module, which may lead to internal damage of the PV layer; 4) the PV cell and the backplate should possess a high breakdown voltage in order to withstand an abnormal surge of current (e.g., lightning strike); 5) the module should be constructed such that when the glass substrate is broken CdS, CdTe and/or other substances, which are possible causes for environmental pollution, are prevented from scattering from the housing; and 6) the construction method used to manufacture the module should be compatible with automation and mass production methods.

Oido has been found to teach inclusion of an empty space (air) in contact with the PV layer and electrodes to address thermal expansion stresses. Oido also has been found to incorporate a free desiccant material, such as zeolite, held within the airspace to control humidity. A hot melt butyl edge seal is used to seal the metal desiccant carrying back plate to the glass front plate and to a strengthening frame. The hot melt butyl provides low permeability to moisture and the desiccant adsorbs moisture that does get through. Units with enclosed desiccant and butyl rubber seal perform better than units with butyl alone. The metal edge frame and back plate provide strength which allows the uncured butyl hot melt to be an adequately strong seal and adhesive. There is a very thin layer between the frame and back cover edges which are both formed to interact closely to provide rigidity. Finally, Oido teaches a layer of protective film is applied to the front of the glass substrate to protect against scattering of the parts should the substrate be broken.

Accordingly, Oido protects a moisture sensitive PV construction by choosing an edge sealing and adhesive material with a low moisture and oxygen permeability and encloses a desiccant with the PV layer both within a free airspace to adsorb moisture over the long life of the unit. The amount of desiccant, permeability of sealant, length of path and area of the diffusion path will determine the amount of time required for humidity to rise inside the unit to a level that will cause degradation of the performance of the module. While Oido teaches a desiccant applied to the free space, Oido has not been found to disclose a sealant layer having a desiccant. Likewise, Oido has not been found to teach applying the sealant in a pumpable manner, which increases manufacturing efficiencies. On the contrary, the method taught by Oido will likely increase the cost of manufacturing, as well as require additional time to apply the desiccant to the free space.

U.S. Pat. No. 5,022,930 to Ackerman et al. makes an improvement over Oido by providing a means for protecting a TFPV layer by enclosing desiccant and an inert gas with means for filling and, if necessary, replacing or replenishing the inert gas. This improvement allows for the exclusion of oxygen and other corrosive gases by purging after assembly and sealing the unit. Thus, Ackerman minimizes moisture levels over a long period of time by using a very thin edge adhesive, which decreases cross-sectional area in the diffusion path, and wide interconnecting lines, which increase the length of the diffusion path. Ackerman also utilizes a desiccant material to adsorb moisture that does ingress into the unit. Ackerman also advances the concept of further extending the life time of the TFPV layer by keeping the moisture level low in the unit by eliminating an edge seal adhesive by securing an impermeable seal by welding the glass substrate directly to the metal back cover. The desiccant inside the unit remains present to adsorb water penetration possibly due to defects in the welding or leaking in the gas filling valves. Like Oido, Ackerman has not been found to disclose a sealant layer having a desiccant or applying the sealant in a pumpable manner, which increases manufacturing efficiencies. Instead, Ackerman discloses filling a void between a backcap and a top electrode layer with desiccant.

U.S. Pat. No. 6,673,997 discloses various prior art that propose to seal a TFPV module consisting of a front glass substrate, a photovoltaic layer and a polymeric protective resin covering the photovoltaic layer and electrodes inside an insulating glass unit. The glass substrate of the module can also serve as one lite of insulating glass (IG) unit where the PV layer does not extend to the border of the glass. The IG unit being of typical well known construction using a metal spacer tube adhered to the perimeter of the PV glass substrate by a polyisobutylene (PIB) based primary seal, the spacer bar filled with desiccant communicating with the airspace containing the PV module through inward facing holes in the tube, and an adhesive outside the tube adhering the spacer tube to the front and rear glass substrates. This provides protection of the TFPV layer from moisture in much the same manner as Oido proposed above with the same elements repositioned. The main difference being the inclusion of the protective polymeric layer being on the inside of the module and directly adhered to the PV layer and the back cover being a glass lite. The spacer tube and outboard curing adhesive providing structural strength and a separate PIB primary seal providing a seal against moisture diffusion.

U.S. Pat. No. 5,478,402 to Hanoka et al. teaches the use of a foam tape to act as a dam to contain laminating layers that are put in position as dry sheets that liquefy during curing to fill the entire space around the PV materials and between the front and back support sheets. Hanoka has not been found to disclose using a desiccant in the sealant layer and/or applying the sealant in a pumpable manner, which increases manufacturing efficiencies.

U.S. Pat. No. 5,667,595 to Vaverka et al. teaches application of a sealing and spacing means along the edge of a solar module, such as a TFPV module, with diagonally opposed corners left open and metal tubes inserted. A laminating/encapsulating liquid resin is poured between the plates through the tubes and cured to form a solid laminating adhesive layer. Vaverka teaches no particular properties for this edge sealing and spacing means other than the ability to seal against the liquid resin for the short period of time required to cure the resin. Vaverka has not been found to disclose using a desiccant in the sealant layer and/or applying the sealant in a pumpable manner. Furthermore, due to Vaverka's intricate manufacturing process, there are many manufacturing inefficiencies.

U.S. Pat. No. 6,673,997 to Blieske et al. teaches an improvement over Vaverka for making modules with moisture sensitive TFPV materials. Blieske provides an elastomeric spacer having a moisture absorbing medium and one or two external adhesive beads extruded around the perimeter of at least one pane. The bead(s) serves to seal the border of the solar modular and to act as a spacer between the two glass plates. Lengths of tubing are also inserted into the two diagonally opposed corner regions of the adhesive bead that provide for the subsequent filling and venting of the hollow space between the two glass panes. The front glass pane is applied to the back pane and compressed until the desired spacing is achieved. When the desired spacing is achieved, the hollow space between the two glass panes is filled with a liquid casting compound by orienting the module in a roughly vertical position and the casting resin substance fills the space via the lower tube, while the upper tube serves for venting. The casting compound typically cures to become a solid layer. After filling, the two tubes are removed and the orifices are sealed using an adhesive. As apparent from the manufacturing steps discussed above, Blieske's manufacturing process is time consuming and inefficient.

U.S. Pat. No. 6,288,326 to Hayashi et al. teaches the use of a steam barrier butyl or PIB applied at the perimeter of the TFPV, where EVA is used as the laminating/encapsulating layer. This improves performance in short term heat plus humidity tests (e.g., at 120° C. and 100% humidity at approximately 28 pounds per square inch). Thus, Hayashi provides an alternative to Nakano using a separate steam barrier. Hayashi does not specify how the steam barrier is applied to the module but states that it is to be cured. Hayashi has not been found to disclose the use of a desiccant material in the sealant layer or application of the sealant layer by means of a pump.

U.S. Pat. No. 6,936,131 to McCormick et al. teaches a desiccated transfer adhesive to protect moisture sensitive organic electronic devices from moisture. McCormick includes a second high barrier (low moisture permeability) adhesive outside the desiccated adhesive gasket to improve the performance of the gasket. The absorbent-loaded transfer adhesive may form a gasket around the periphery of the device, or may cover the entire device and its periphery. McCormick has been found to disclose a transfer adhesive that is generally suited to small parts, not the perimeter of PV panels due to high cost and manufacturing inefficiencies associated with transfer adhesives.

U.S. Patent Application Publication No. 2003/0079772 to Gittings et al. teaches an edge seal for a TFPV module using a poly ethyl vinyl acetate (EVA) laminating/encapsulating layer and a desiccated butyl tape as a border seal. The use of the desiccated low permeability seal improves the performance in damp heat versus a module having an un-desiccated seal as determined by accelerated moisture resistance tests as set forth in the International Electrical Commission (IEC) 1215 International Standard. Gittings specifies a desiccant content and permeability and claims a method of assembling a TFPV using the tape and an EVA sheet with vacuum lamination and curing of the EVA. There are a variety of drawbacks with Gittings' desiccated tape including, inefficiencies in manufacturing process, prefabrication of the desiccated tape is normally required and difficulty in obtaining an airtight seal using a tape material, etc.

In addition to the drawbacks listed above, there are a variety of drawbacks associated with manual and/or automated systems for applying tapes on TFPV panels. Such drawbacks include, manufacturing inefficiencies, trapped air, overlapping corners, additional time to mitre cut corners to obtain continuous seals, etc.

### SUMMARY OF THE INVENTION

Based on the prior art discussed above, a need exists for a sealant containing a desiccant material to be easily applied in a liquid form by a pump during manufacturing of a thin film photovoltaic panels (TFPPs). Such improvements simplify the manufacturing process associated with TFPPs, provide a longer lifespan for TFPPs by increasing time for moisture to penetrate the seal and reach the photovoltaic semiconductor material along the edges of the panel.

One aspect of the present invention relates to thin film photovoltaic panel including: a first substrate; a second substrate; a photovoltaic layer disposed between the first substrate and the second substrate; a sealant applied in a liquid form by a pump around a periphery of a planar surface of at least one of the first substrate or second substrate, wherein the sealant includes a desiccant material and the sealant changes from the liquid form to a solid form upon cooling; and a first adhesive layer disposed between the first substrate and the second substrate for securing the first substrate to the second substrate, wherein the first adhesive layer is disposed between the photovoltaic layer and at least one of the first substrate or second substrate.

Another aspect of the present invention relates to a method for manufacturing a thin film photovoltaic panel including: providing a photovoltaic layer disposed between a first substrate and a second substrate, wherein at least one of the first substrate and second substrate include a planar surface and at least one edge; applying a sealant layer in a liquid form by a pump around a periphery of a portion of the planar surface of the first substrate, wherein the sealant layer includes a desiccant material, wherein the sealant changes from the liquid to a solid form upon cooling; applying a first adhesive layer between the first substrate and the second substrate, wherein the first adhesive layer is disposed between the photovoltaic layer and at least one of the first and second substrate; and securing at least a portion of the first substrate to the second substrate with the first adhesive layer by applying a force to at least one of the first substrate and the second substrate.

Another aspect of the invention relates to a thin film photovoltaic panel including: a first substrate; a second substrate; a photovoltaic layer disposed between the first substrate and the second substrate; a desiccated sealant means disposed around a periphery of a planar surface of at least one of the first substrate or second substrate, wherein the desiccated sealant means forms a seal between the first substrate and the second substrate to increase the time lag for moisture to penetrate between the first substrate and the second substrate; and a first adhesive layer disposed between the first substrate and the second substrate for securing the first substrate to the second substrate, wherein the first adhesive layer is disposed between the photovoltaic layer and at least one of the first substrate or second substrate.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended thereto.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF DRAWINGS

FIG. 1A is an exemplary cross-sectional view of layers associated with the thin film photovoltaic panel in accordance with aspects of the present invention.

FIG. 1B is an exemplary front view of the thin film photovoltaic panel in accordance with aspects of the present invention.

FIG. 2 is an exemplary theoretical chart comparing the moisture vapor transmission rate of a first sealant and a second sealant having a desiccant material in accordance with aspects of the present invention.

FIGS. 3 and 4 are a schematic cross-sectional view of layers associated with the thin film photovoltaic panel in accordance with other aspects of the present invention.

FIG. 5 is a flow diagram schematically illustrating a method for fabricating a thin film photovoltaic panel in accordance with aspects of the present invention.

It should be appreciated that for simplicity and clarity of illustration, elements shown in the figures have not necessarily been drawn to scale. For example, the dimensions of some of the elements are exaggerated relative to each other for clarity. Further, where considered appropriate, reference numerals have been repeated among the figures to indicate corresponding elements.

Furthermore, it should be appreciated that the process steps and structures described below do not form a complete process flow for manufacturing solar panels. The present invention can be practiced in conjunction with thin film photovoltaic panel (or solar panel) fabrication techniques currently used in the art, and only so much of the commonly practiced process steps are included as are necessary for an understanding of the present invention.

### DETAILED DESCRIPTION OF THE INVENTION

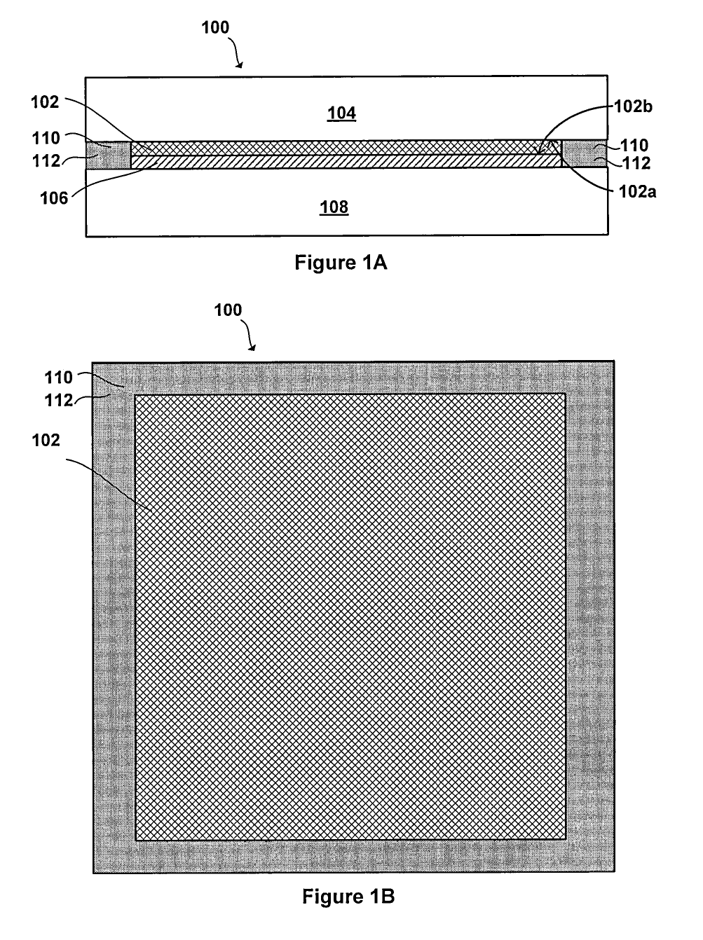

One embodiment of a thin film photovoltaic panel (TFPP) 100 (also commonly referred to as a solar panel) in accordance with aspects of the present invention is shown in a cross-sectional schematic view in FIG. 1A and a top view in FIG. 1B. The TFPP 100 includes a photovoltaic layer 102. A first surface 102a of the photovoltaic layer 102 may be disposed on and attached to a front panel 104 (also referred to herein as a substrate). As used herein, the front panel generally refers to a surface of the module that faces the source of solar energy. On a second surface 102b of the photovoltaic layer 102 may be disposed an adhesive layer 106. The adhesive layer 106 forms a bond between the photovoltaic layer 102 and a backing panel 108. A sealant layer 110 is disposed between the front panel 104 and the backing panel 108 (also referred to herein as a substrate). The sealant layer 110 includes a desiccant material 112. The sealant layer 110 functions to prevent moisture from entering into the panel and contacting the photovoltaic layer 102. The desiccant material 112 generally increases the time for moisture to penetrate the seal and reach the photovoltaic layer. As shown in FIG. 1A, the sealant layer 110 may be disposed on one or more planar surfaces of the front panel 104 and/or the backing panel 108. Preferably, the sealant layer 110 with the desiccant material 112 is located at and/or near one or more edges of the front panel 104 and/or backing panel 108.

The TFPP 100 may be fabricated by depositing the photovoltaic layer 102, e.g., amorphous silicon, cadmium diselenide (CdS), cadmium telluride (Cd/Te), copper indium diselenide (CIS), copper indium gallium diselenide (CIGS), etc., on the front panel 104 and/or the backing panel 108 (in another embodiment). The front panel 104 and backing panel may be formed of any appropriate material, and due to the desirability of the front panel to be transparent and/or highly transmissive, in many instances the material is glass. The backing panel 108 does not necessarily need to be a light transmissive material.

The photovoltaic layer 102 may be deposited by any appropriate means known in the art. For example, amorphous silicon may be deposited by chemical vapor deposition (CVD), by physical vapor deposition (PVD), by sputtering or by any other known method. The CVD methods may include any of a variety of methods, for example, CVD, PECVD, RTCVD, ALCVD, MOCVD or LPCVD.

The adhesive layer 106 may be applied to be in direct contact with the photovoltaic layer 102 in an embodiment such as shown in FIG. 1A. The adhesive layer is also generally in contact with the backing panel 108. Of course, the adhesive may be initially applied to either the backing panel 108 or to the photovoltaic layer 102 or a protective layer (not shown) and/or tying layer (not shown), and then subsequently applied to the opposite layer when the panels are brought into sealing contact. Thus, the adhesive layer 106 is disposed between and adheres together the photovoltaic layer 102 and the backing panel 104, with the optional protective layer and/or tying layer intervening between these layers in some embodiments.

The adhesive layer 106 is often referred to as an assembly adhesive or a laminating adhesive, since it is used to assemble and hold together the elements of the solar panel 100. The adhesive layer 106 may include a single component curing hot melt adhesive and/or a multi-component curing adhesive. The adhesive layer 106 may be applied to the front panel 104 containing the photovoltaic layer 102 using any of the known methods to substantially cover the entire substrate and or a portion of the substrate as desired. In addition, the adhesive layer 106 may be applied to the backing panel 108. Exemplary adhesive materials for the adhesive layer 106 include, for example, ethylene vinyl acetate (EVA), ionomer (e.g., SURYLN®), polyvinyl butyral (PVB), etc.

The sealant layer 110 containing desiccant material 112 is applied substantially on at least one planar surface of the front panel 104 and/or backing panel 108. For example, the sealant layer 110 may be applied just inboard of an edge of the front panel and/or the backing panel 108. Preferably, the sealant layer 110 does not overlap the photovoltaic layer 102 and/or the adhesive layer 106. In another embodiment, the sealant layer 110 may extend to the edge of the substrate 104 and/or backing panel 108. In another embodiment, the sealant layer 110 may extend (or protrude) beyond the edge of the front panel 104 and/or backing panel 108.

The sealant layer 110 functions to prevent moisture from entering into the panel and contacting the photovoltaic layer 102. The sealant layer 110 provides the TFPP 100 with a relatively low moisture vapor transmission rate (MVTR) as measured in accordance with ASTM F1249 at film thickness of 0.060″ at a temperature of 37.8° C. For example, the sealant layer 110 has a MVTR of less than 3 grams/m²/day. The sealant layer 110 generally bonds to the front panel (substrate) 104 and the backing panel 108 and slows the progression of moisture vapor into the panel 100 from the edges of the front panel 104 and backing panel 108. The moisture vapor is slowed through the sealant layer 110 due to the low MVTR of the sealant. Exemplary sealant materials for the sealant layer 110 include base polymers, for example, polyisobutylene (PIB), butyl rubber, VAMAC® ethylene acrylic elastomers (manufactured by DuPont), Hypalon® chlorosulfonated polyethylene (manufactured by DuPont)

As stated above, the sealant layer 110 includes a desiccant material 112. The desiccant material 112 generally increases the time for moisture to penetrate the sealant layer 110 and reach the photovoltaic layer 102. The desiccant material 112 is preferably a zeolite molecular sieve, at a concentration of less than 20 weight percent (wt. %). The desiccant material acts to increase the time lag until steady state moisture vapor transmission through the sealant occurs by adsorbing moisture into the zeolite cage structure and preventing any moisture from penetrating into the laminating adhesive film and photovoltaic layer 102 until all the desiccant material in the sealant layer 110 has been fully or near fully saturated. By preventing moisture from entering into the photovoltaic layer 102 from an edge of the panel 100, the durability and/or lifetime of the panel and/or the photovoltaic layer 102 is increased. The phrase “desiccated sealant means”, as used herein, means any sealant material and desiccant material described herein along with any and all equivalents of the sealant material, desiccant material and/or combination of sealant material and/or desiccant material.

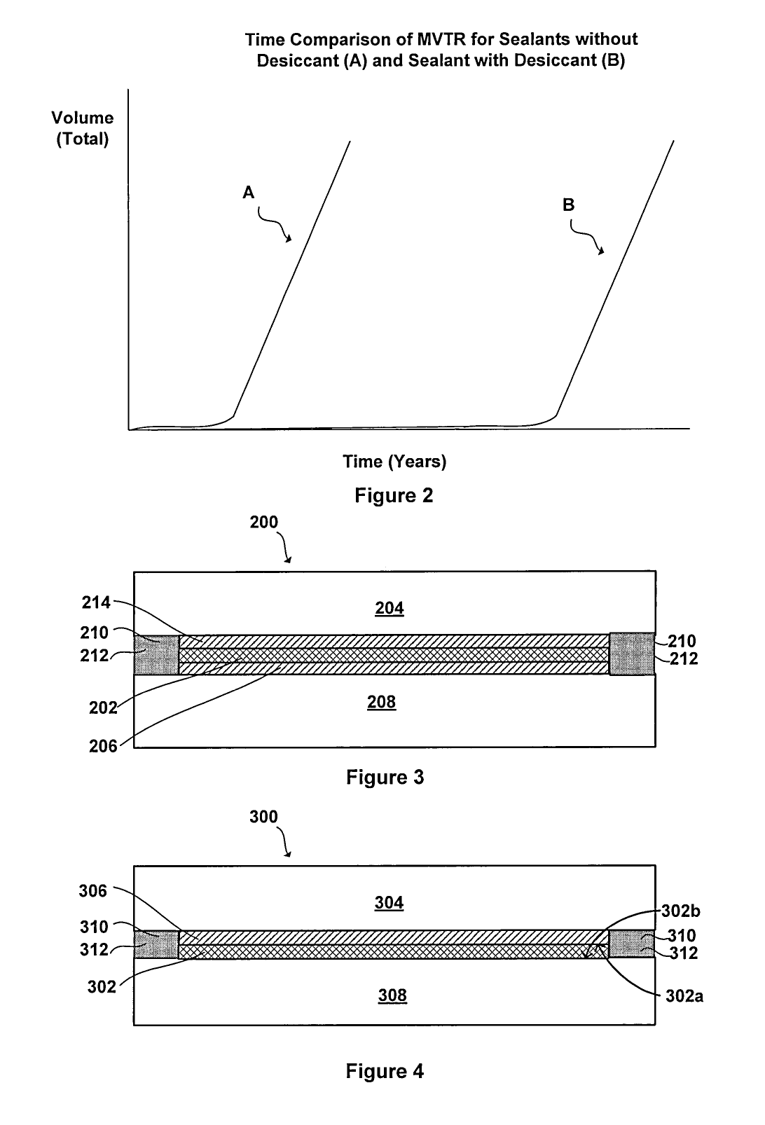

Referring to FIG. 2, an exemplary graph illustrating a theoretical MVTR for two sealants is illustrated. The first sealant (indicated generally by the reference “A”) does not contain any desiccant material. The second sealant (indicated generally by the reference “B”) is identical to the first sealant, except that it includes a desiccant material. As shown, the two graphs are substantially identical in terms of the slope of transmission rate. However, the second sealant (B) takes significantly more time before moisture vapor is transmitted. This time lag will vary based on the type of desiccant material and the percentage desiccant material in the sealant. Thus, the desiccant material increases the time for moisture to penetrate the sealant layer. For additional information relating to the relationship between time lag and desiccant volume, reference is made to a paper article written by D. R. Paul and D. R. Kemp entitled “The Diffusion Time Lag In Polymer Membranes Containing Absorptive Fillers”, J. POLYMER SCI.; Symposium No. 41, 79-93 (1973), which is incorporated herein by reference.

As stated above, the sealant layer 110 is a liquid applied sealant that is applied by a pump. For example, a dispensing pump is placed within a container (e.g., a barrel) and/or on top of the container containing the pumpable sealant material. The pumpable sealant material is generally pumped from the barrel through the pump and output through an applicator attached to hose. As used herein, a composition is considered “pumpable” if, when tested per ASTM D-1238, Procedure B using a 1100 gram load and an 8 gram sample at 190° C., the melt flow time of the composition is no more than 180 seconds. Melt flow is measured using a 2.54 cm piston travel as mandated by section 10.1.2.5 of the ASTM D-1238 procedure. One of ordinary skill in the art will readily appreciate that various types of pumping equipment may be used in accordance with aspects of the present invention based on the melt flow time of the composition. For example, compositions having a melt flow of 60 seconds or less may be pumped using standard pumping equipment (e.g., a Graco pumping device, such as a Therm-O-Flow heated reciprocating piston pump). For compositions having a melt flow between 60 seconds and 180 seconds, it may desirable to utilize a pump that can handle higher viscosity materials (e.g., a gear pump such as the MAHR HV drum pump). Higher melt flow time between 60 and 180 seconds may still be used but require higher viscosity pumping equipment, such as a MAHR HV drum pump. For additional information related to pumpability reference is made to U.S. Pat. No. 6,112,477, which is incorporated by reference.

The applicator may be any desired shape and size. Suitable shapes are circular, semi-circular, rectangular, square, diamond, etc. The applicator may be manually directed or computer-controlled to deliver a predetermined pattern of sealant material on any desired layer (e.g. front panel 104, backing panel 108, protective layer, tying layer, etc.) of the TFPP 100. The sealant material is generally applied in liquid form and may cool to a solid state upon combining the front panel 104 and the backing panel 108. Preferably, the sealant layer 110 is applied along the periphery of the front panel and/or backing panel 108, as shown in FIGS. 1A and 1B.

The following description illustrates additional embodiments for the present invention. Like elements have been given similar reference numbers. For example, photovoltaic layer 102 is referred to below as 202, 302, and 402 in the various embodiments. For the sake of brevity, the description applicable to each element for any one of the embodiments is applicable to all of the other embodiments disclosed herein.

Another aspect of the present invention relates to a TFPP 200 illustrated in FIG. 3. The TFPP 200 includes a first substrate 204; a second substrate 208 and a photovoltaic layer 202 disposed between the first substrate 204 and the second substrate 208. A sealant layer 210 is applied in a liquid form by a pump around a periphery of a planar surface of at least one of the first substrate 204 or second substrate 208. The sealant layer 210 includes a desiccant material 212. The TFPP 200 further includes a first adhesive layer 206 disposed between the first substrate 204 and the second substrate 206. In one embodiment, the first adhesive layer 206 secures the second substrate 208 to the photovoltaic layer 202. Optionally, a second adhesive layer 214 is provided. The second adhesive layer 214 is disposed between the first substrate and the second substrate. Preferably, the second adhesive layer 214 is disposed on an opposing side of the photovoltaic layer 202 in which the first adhesive layer 206 is applied. In particular, the second adhesive layer 214 secures the first substrate 204 to the photovoltaic layer 202.

One of ordinary skill will readily appreciate that the adhesive layer 206 may be deposited on the backing panel 208 and/or the adhesive layer 214 may be deposited on the front panel 204. In addition, the photovoltaic layer 202 may be deposited on either the front panel construct (e.g., front panel 204 with adhesive layer 214 or the back panel construct (e.g., backing panel 208 with adhesive layer 206). In addition, the adhesive layer 206 may be deposited on a substrate (e.g., PET) or other supporting surface (e.g., a film) and placed between the front panel 204 construct and the backing panel 208 construct.

Another aspect of the invention is illustrated in FIG. 4. The TFPP 300 includes a first substrate 304; a second substrate 308 and a photovoltaic layer 302 disposed between the first substrate 304 and the second substrate 308. In this embodiment, the photovoltaic layer 302 is deposited on second substrate 308.

A first surface 302a of the photovoltaic layer 302 may be disposed on an adhesive layer 306. A second surface 302b of the photovoltaic layer 302 may be disposed and attached to the backing panel 308 (also referred to herein as a substrate). The adhesive layer 306 forms a bond between the photovoltaic layer 302 and the front panel 304. A sealant layer 310 is disposed between the front panel 304 and the backing panel 308.

The sealant layer 310 includes a desiccant material 312. The sealant layer 310 functions to prevent moisture from entering into the panel and contacting the photovoltaic layer 302. The desiccant material 312 generally increases the time for moisture to penetrate the sealant layer 310 and reach the photovoltaic layer 302. As shown in FIG. 4, the sealant layer 310 may be disposed on one or more planar surfaces of the front panel 304 and/or the backing panel 308. Preferably, the sealant layer 310 with the desiccant material 312 is located at and/or near one or more edges of the front panel 304 and/or backing panel 308.

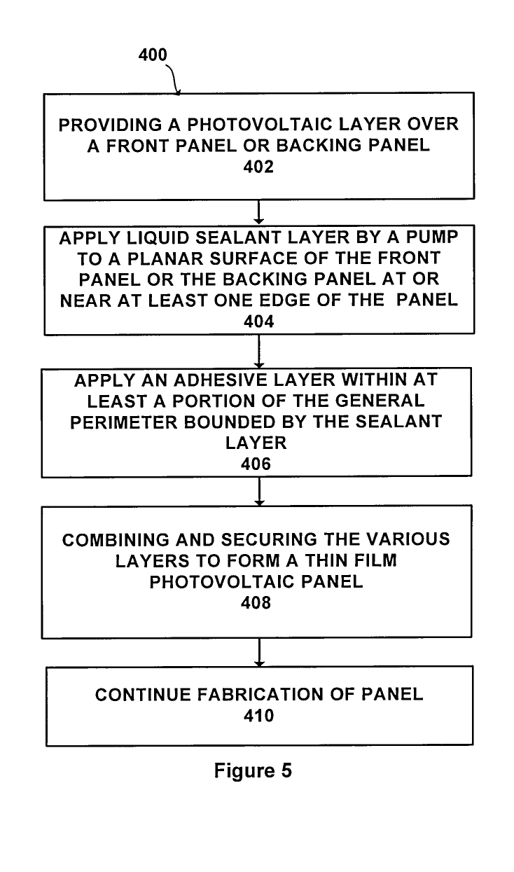

FIG. 5 is a flow diagram schematically illustrating an exemplary method 400 of fabricating a TFPP in accordance with aspects of the present invention. As shown in FIG. 5, at block 402, a photovoltaic layer is provided. The photovoltaic layer may be deposited over a substrate. For example, the photovoltaic layer will have been deposited by an appropriate process to one surface of a front panel, backing panel and/or deposited on a separate support construct to be placed between the front panel and the backing panel such as that described above. In addition, the photovoltaic layer usually will have been separated into individual photovoltaic cells, or photocells. Each of the photocells will have been electrically connected, as appropriate to the design of the solar cell. Such matters may be appropriately designed or selected by those of skill in the art, and the present invention is not limited to any particular form of photovoltaic layer. Optionally, the photovoltaic layer may deposited over a substrate that has an adhesive layer previously deposited thereon, such that the photovoltaic layer is in contact with the adhesive layer and the adhesive layer is in contact with the substrate.

At block 404, a liquid sealant layer containing a desiccant material is applied by a pump to a portion of a planar surface of the front panel and/or backing panel. Preferably, the adhesive is applied to the surface in which the photovoltaic material has been applied and the liquid sealant is applied at or near at least one edge of the substrate 104 and/or back panel 108. Preferably, the liquid sealant is applied around the periphery of the front panel and/or backing panel, as desired. As stated above, the application of the liquid sealant layer may be manually and/or computer-controlled. In one embodiment, the liquid sealant layer may be applied in a parallel direction on two sides of desired front panel and/or backing panel and then applied in a parallel direction on the two remaining sides. Alternatively, the liquid sealant layer may be applied serially (side by side) around the perimeter of front panel and/or backing panel.

At block 406, an adhesive layer is applied within the general perimeter bounded by the sealant layer 110, as provided in the second step. The adhesive layer 106 may be applied to the entire surface of the area bounded by the sealant layer 110 and/or a portion of the area bounded by the sealant layer 110. As one of ordinary skill in the art would readily appreciate, the adhesive layer may be applied prior to block 404, at the same time as block 404, and/or after block 404. All such modifications are intended to be within the scope of the present invention.

At block 408, the respective layers of the TFPP, including the front panel, photovoltaic material layer, sealant layer, adhesive layer and backing panel are brought together and secured. The components are generally secured by a compressive force that is applied to the TFPP structure. The force can be applied by any known means in the art. For example, the TFPP structure may be subjected to a compressive force. The TFPP structure may be pressed together with a bladder or platen. In addition, the TFPP structure may be compressed together through a set of rollers. Depending on the adhesive, the substrate, photovoltaic material, sealant layer, adhesive layer and backing panel may also be brought together by the presence of vacuum and/or heat. For example, the TFPP structure may be placed into a vacuum laminator, such as a SPI Laminator 350 from Spire Corporation. The TFPP module may be heated by a platen to 160° C. under vacuum followed by vacuum and pressure being applied by a bladder of the laminator.

Application of such forces helps the adhesive layer to wet the surfaces to which it will be attached, to provide an intimate, complete attachment. The adhesive layer should be applied in a manner so as to avoid the formation of air pockets or bubbles between the respective front and back panels. As is known in the art, such air pockets or bubbles can lead to failure of the TFPP in use.

At block 410, other fabrication steps associated with the TFPP may be performed. In general, as the TFPP is assembled, the module wires are electrically connected to the photovoltaic layer. When the backing panel and the front panel (together with the photovoltaic layer) are brought together, the module wires will generally extend through the applied adhesive layers and into and through the module wire openings (not shown). The module wire openings may be filled with an appropriate adhesive and/or sealant at any appropriate time. In addition, when the backing panel and the front panel (together with the photovoltaic layer) are brought together, the module wires may extend out the side of the module through the sealant layer. In such case, the sealant layer will encase the module wire openings.

Further features, advantages, and embodiments are described in the examples.

### EXAMPLES

Example 1 includes a hot-melt sealant comprised of the following chemical composition:

| Component | Chemical Name | Manufacturer | % (Total Wt) |
|---|---|---|---|
| Butyl 268 | Butyl rubber | Exxon | 10 |
| Rextac 2585 | Amorphous | Huntsman | 40 |
| | polyalphaolefin | | |
| H-100 W | Hydrocarbon Resin | Eastman | 10 |
| MOLSIV | Molecular Sieve | UOP | 19 |
| Hubercarb Q6 | Calcium carbonate | Huber | 16 |
| Hi-Sil 233 | Silicon Dioxide | PPG | 5% |
| TOTAL | | | 100 |

In accordance with another exemplary embodiment, Example 2 includes a curing hot-melt sealant comprised of the following chemical composition:

| Component | Chemical Name | Manufacturer | Percent |
|---|---|---|---|
| B-10 PIB | Polyisobutylene | BASF | 10 |
| Rextac 2585 | Amorphous polyalphaolefin | Huntsman | 30 |
| DFDA-5451NT | Moisture curing PE | Dow | 19 |
| DFDA-5481 NT | Moisture curing PE catalyst | Dow | 1 |
| H-100 W | Hydrocarbon Resin | Eastman | 10 |
| MOLSIV | Molecular Sieve | UOP | 19 |
| Hubercarb Q6 | Calcium carbonate | Huber | 11 |
| TOTAL | | | 100 |

The sealant compositions of Example 1 and Example 2 may be mixed in a sigma type mixer until homogenous and transferred to a five-gallon bucket that can be placed under a pumping device such as a (e.g., a Graco pumping device, a Therm-O-Flow heated reciprocating piston pump). The pumping device is generally equipped with a heated hose and heated dispensing nozzle with a tip capable of producing a flat bead of sealant from its end.

In one exemplary method of use, a flat bead of sealant is pumped from the five-gallon bucket onto the surface of a first substrate of a photovoltaic module at or near the perimeter edge. Assuming a square or rectangular module, the sealant is placed on the periphery of all four sides. At the periphery corners, the sealant could be butted up against itself at right angles or it could be overlapped in order to make a continuous bead of sealant around the entire perimeter of the photovoltaic module. Inside the perimeter of the hot melt sealant, a sheet of a curing laminating adhesive, typically ethylene vinyl acetate (EVA) is placed. A second substrate may then be placed on top of the first substrate so as to create a sandwich structure with the laminating adhesive(s), photovoltaic semiconductor material, and one of the above sealants formed between the two substrates. This module would then be placed into a vacuum laminator, such as a SPI Laminator 350 from Spire Corporation. The module may be heated by a platen to 160° C. under a vacuum and followed by vacuum and pressure being applied by the bladder of the laminator. A typical cycle for this lamination is to place the module onto the 160° C. platen under vacuum for approximately five minutes. This allows air to be removed from between the substrates that may have been trapped when the laminating adhesive was placed upon one of the substrates. After this five minute de-airing and heating sequence, the internal bladder is inflated to press the two substrates together while maintaining the vacuum around the module. This vacuum—pressing—heating cycle may last for approximately 10 minutes. After this cycle, the module has completed its lamination phase and is ready for the next phase of the manufacturing cycle.

Although the invention has been shown and described with respect to certain preferred embodiments, equivalent alterations and modifications will occur to others skilled in the art upon reading and understanding this specification and the annexed drawings. In particular regard to the various functions performed by the above described integers (components, assemblies, devices, compositions, steps, etc.), the terms (including a reference to a “means”) used to describe such integers are intended to correspond, unless otherwise indicated, to any integer which performs the specified function of the described integer (i.e., that is functionally equivalent), even though not structurally equivalent to the disclosed structure which performs the function in the herein illustrated exemplary embodiment or embodiments of the invention. In addition, any recitation of “means” or “means for” is intended to evoke a means-plus-function reading of an element and a claim, whereas, any elements that do not specifically use the recitation “means” or “means for”, are not intended to be read as means-plus-function elements. It should also be noted that although the specification lists method steps occurring in a particular order, these steps may be executed in any order, or at the same time. In addition, while a particular feature of the invention may have been described above with respect to only one of several illustrated embodiments, such feature may be combined with one or more other features of the other embodiments, as maybe desired and advantageous for any given or particular application.

What is claimed is:

1. A method for manufacturing a thin film photovoltaic panel comprising:
providing a photovoltaic layer disposed between a first substrate and a second substrate, wherein at least one of the first substrate and second substrate include a planar surface and at least one edge;
applying a sealant layer in a liquid form by a pump around a periphery of a portion of the planar surface of the first substrate, wherein the sealant layer includes a desiccant material, wherein the sealant changes from the liquid to a solid form upon cooling;
applying a first adhesive layer between the first substrate and the second substrate, wherein the first adhesive layer is disposed between the photovoltaic layer and at least one of the first and second substrate; and
securing at least a portion of the first substrate to the second substrate with the first adhesive layer by applying a force to at least one of the first substrate and the second substrate.

2. The method of claim 1, wherein the sealant layer has a moisture vapor transmission rate of less than 3 g/m²/day, as measured in accordance with ASTM F1249 Standard.

3. The method of claim 1, wherein the desiccant material includes a zeolite molecular sieve.

4. The method of claim 1, wherein the desiccant material has a concentration of less than about 20 weight %.

5. The method of claim 1, wherein the sealant layer is formed from a hot melt sealant.

6. The method of claim 1, wherein the sealant layer is a curing hot melt adhesive.

7. The method of claim 1, wherein the first adhesive layer is disposed within the periphery of the sealant layer.

8. The method of claim 1 further including applying a second adhesive layer disposed between the first substrate and the second substrate, wherein the second adhesive layer is disposed on an opposing side of the photovoltaic layer in which the first adhesive layer is disposed.

9. The method of claim 1, wherein the applied force is a compressive force.

10. The method of claim 9, wherein the applied force is applied by a platen and/or a bladder.

11. The method of claim 9, wherein the applied force is applied by rollers.

12. The method of claim 9, wherein the applied force is applied to the thin film photovoltaic panel while the entire thin film photovoltaic panel is under a vacuum.

13. A thin film photovoltaic panel comprising:
a first substrate;
a second substrate;
a photovoltaic layer disposed between the first substrate and the second substrate;
a desiccated sealant means disposed around a periphery of a planar surface of at least one of the first substrate or second substrate, wherein the desiccated sealant means forms a seal between the first substrate and the second substrate to increase the time lag for moisture to penetrate between the first substrate and the second substrate; and
a first adhesive layer disposed between the first substrate and the second substrate for securing the first substrate to the second substrate, wherein the first adhesive layer is disposed between the photovoltaic layer and at least one of the first substrate or second substrate.

14. The thin film photovoltaic panel of claim 13, wherein the desiccated sealant means is a liquid pumpable sealant that changes from a liquid form to a solid form upon assembly of the first substrate and the second substrate.

15. The thin film photovoltaic panel of claim 14, wherein the desiccated sealant means has a moisture vapor transmission rate of less than 3 g/m2/day, as measured in accordance with ASTM F1249 Standard.

16. The thin film photovoltaic panel of claim 15, wherein the desiccated sealant means includes a zeolite molecular sieve.

17. The thin film photovoltaic panel of claim 13, wherein the desiccated sealant means is a hot melt sealant.

18. The thin film photovoltaic panel of claim 13, wherein the desiccated sealant means is a curing hot melt sealant.

19. The thin film photovoltaic panel of claim 13, wherein the desiccated sealant means has a concentration of less than about 20 weight %.

20. The thin film photovoltaic panel of claim 13, further including a second adhesive layer disposed between the first substrate and the second substrate, wherein the second adhesive layer is disposed on an opposing side of the photovoltaic layer in which the first adhesive layer is applied.

21. The thin film photovoltaic panel of claim 13, wherein the desiccated sealant means extends to an outer edge of at least one of the first substrate or the second substrate.

22. The thin film photovoltaic panel of claim 13, wherein the desiccated sealant means extends past an outer edge of the at least one of the first substrate or the second substrate.

23. A thin film photovoltaic panel comprising:
a first substrate;
a second substrate;
a photovoltaic layer disposed between the first substrate and the second substrate;
a sealant applied in a liquid form by a pump around a periphery of a planar surface of at least one of the first substrate or second substrate, wherein the sealant includes a desiccant material and the sealant changes from the liquid form to a solid form upon cooling; and
a first adhesive layer disposed between the first substrate and the second substrate for securing the first substrate to the second substrate, wherein the first adhesive layer is disposed between the photovoltaic layer and at least one of the first substrate or second substrate.

24. The thin film photovoltaic panel of claim 23, wherein the sealant has a moisture vapor transmission rate of less than 3 g/m2/day, as measured in accordance with ASTM F1249 Standard.

25. The thin film photovoltaic panel of claim 23, wherein the desiccant material includes a zeolite molecular sieve.

26. The thin film photovoltaic panel of claim 23, wherein the desiccant material has a concentration of less than about 20 weight %.

27. The thin film photovoltaic panel of claim 23, wherein the sealant is a hot melt sealant.

28. The thin film photovoltaic panel of claim 27, wherein the sealant is a curing hot melt sealant.

29. The thin film photovoltaic panel of claim 23, further including a second adhesive layer disposed between the first substrate and the second substrate, wherein the second adhesive layer is disposed on an opposing side of the photovoltaic layer in which the first adhesive layer is applied.

30. The thin film photovoltaic panel of claim 23, wherein the sealant layer extends to an outer edge of at least one of the first substrate or the second substrate.

31. The thin film photovoltaic panel of claim 23, wherein the sealant layer extends past an outer edge of the at least one of the first substrate or the second substrate.

32. A thin film photovoltaic panel comprising:
a first substrate;
a second substrate;
a photovoltaic layer disposed between the first substrate and the second substrate;
a hot melt liquid sealant applied around a periphery of a planar surface of at least one of the first substrate or the second substrate, wherein the hot melt liquid sealant has a moisture vapor transmission rate of less than 3 g/m²/day, as measured in accordance with ASTM F1249 Standard and includes a desiccant material having a zeolite molecular sieve, wherein the desiccant material has a concentration of less than about 20 weight % and the hot melt sealant changes from the liquid form to a solid form upon cooling; and
a first adhesive layer disposed between the first substrate and the second substrate for securing the first substrate to the second substrate, wherein the first adhesive layer is disposed between the photovoltaic layer and at least one of the first substrate or second substrate.
